(19) United States
(12) Patent Application Publication
(10) Pub. No.: US 2024/0396153 A1
(43) Pub. Date: Nov. 28, 2024

(54) WIRING MODULE AND POWER STORAGE MODULE

(71) Applicants: AUTONETWORKS TECHNOLOGIES, LTD., Mie (JP); SUMITOMO WIRING SYSTEMS, LTD., Mie (JP); SUMITOMO ELECTRIC INDUSTRIES, LTD., Osaka (JP)

(72) Inventors: Yuhei YAMADA, Osaka (JP); Hideo TAKAHASHI, Osaka (JP)

(73) Assignees: AUTONETWORKS TECHNOLOGIES, LTD., Mie (JP); SUMITOMO WIRING SYSTEMS, LTD., Mie (JP); SUMITOMO ELECTRIC INDUSTRIES, LTD., Osaka (JP)

(21) Appl. No.: 18/289,208

(22) PCT Filed: May 13, 2022
(86) PCT No.: PCT/JP2022/020167

§ 371 Date: Jun. 21, 2024

(30) Foreign Application Priority Data
May 17, 2021 (JP) 2021-082940

(51) Int. Cl. H01M 50/298; H01M 10/48; H01M 50/209; H01M 50/519; H05K 1/02; H05K 1/18

(52) U.S. Cl. CPC H01M 50/298; H01M 10/482; H01M 50/209; H01M 50/519; H05K 1/0277; H05K 1/189; H05K 2201/10037; H05K 2201/10151

(57) ABSTRACT

A wiring module 20 includes: a flexible substrate 30 provided with a mounting portion 32, a relay portion 33 that is continuous with the mounting portion 32, and conductive paths 42 and 43 including a connection land 43A disposed on the relay portion 33; a temperature measurement element 50 mounted on the mounting portion 32; a reinforcement member 60 disposed along the mounting portion 32 and the relay portion 33 and fixed to the mounting portion 32; a conductive busbar 70 connected to the electrode terminals 12 and 13; and a conductive relay member 80 that electrically connects the connection land 43A and the busbar 70 to each other, in which the relay member 80 includes a relay base portion 81 connected to the busbar 70, and a plate spring portion 82 that is continuous with the relay base portion 81, overlaps the relay portion 33 and is electrically connected to the connection land 43A, and biases the reinforcement member 60 toward the temperature measurement surface 11F.

### TECHNICAL FIELD

Technology disclosed in this specification relates to a wiring module and a power storage module.

### BACKGROUND ART

A power storage device provided with a power storage battery, a temperature sensor for detecting the surface temperature of the power storage battery, and a holding device that holds the temperature sensor is known. The holding device includes an elastic body that biases the temperature sensor so as to abut against the surface of the power storage battery. As a result, the surface temperature of the power storage battery can be stably detected. Because such a holding device needs to have a structure for receiving a counterforce from the elastic body, the holding device is supported by some kind of structure provided in the power storage device, such as a housing that houses the power storage battery or a support base member that supports a wiring member (see Patent Document 1).

### CITATION LIST

### Patent Documents

Patent Document 1: JP 2013-206619A

### SUMMARY OF INVENTION

### Technical Problem

With the above configuration, a structure for mounting a temperature measurement element tends to be complicated. For the purpose of weight reduction, cost reduction, and the like, there is a need to enable accurate temperature measurement with a simpler configuration.

### Solution to Problem

A wiring module disclosed in this specification is a wiring module to be attached to a power storage element provided with an electrode terminal and having a temperature measurement surface, the wiring module including: a flexible substrate provided with a mounting portion, a relay portion that is continuous with the mounting portion, and a conductive path including a connection land disposed on the relay portion; a temperature measurement element mounted on the mounting portion; a reinforcement member disposed along the mounting portion and the relay portion and fixed to the mounting portion; a conductive connection member connected to the electrode terminal; and a conductive relay member that electrically connects the connection land and the connection member to each other, in which the relay member includes a relay base portion connected to the connection member, and a plate spring portion that is continuous with the relay base portion, overlaps the relay portion and is electrically connected to the connection land, and biases the reinforcement member toward the temperature measurement surface.

Further, a power storage module disclosed in this specification includes: a power storage element provided with an electrode terminal and having a temperature measurement surface; and a wiring module attached to the power storage element, in which the wiring module includes a flexible substrate provided with a mounting portion, a relay portion that is continuous with the mounting portion, and a conductive path including a connection land disposed on the relay portion, a temperature measurement element mounted on the mounting portion, a reinforcement member disposed along the mounting portion and the relay portion and fixed to the mounting portion, a conductive connection member connected to the electrode terminal, and a conductive relay member that electrically connects the connection land and the connection member to each other, in which the relay member includes a relay base portion connected to the connection member, and a plate spring portion that is continuous with the relay base portion, overlaps the relay portion and is electrically connected to the connection land, and biases the reinforcement member toward the temperature measurement surface.

### Advantageous Effects of Invention

According to the wiring module and the power storage module disclosed in this specification, heat generated by the power storage element is reliably transferred to the temperature measurement element via the reinforcement member and the mounting portion.

### BRIEF DESCRIPTION OF DRAWINGS

FIG. 1 is an overall perspective view of a power storage module according to an embodiment.

FIG. 2 is an enlarged plan view of a portion of a power storage module according to an embodiment.

FIG. 3 is a cross-sectional view taken along line A-A in FIG. 2.

FIG. 4 is a cross-sectional view taken along line B-B in FIG. 3.

FIG. 5 is a cross-sectional view taken along line C-C in FIG. 3.

FIG. 6 is an enlarged view of a frame F in FIG. 2.

### DESCRIPTION OF EMBODIMENTS

### Overview of Embodiments

A wiring module disclosed in this specification is a wiring module to be attached to a power storage element provided with an electrode terminal and having a temperature measurement surface, the wiring module including: a flexible substrate provided with a mounting portion, a relay portion that is continuous with the mounting portion, and a conductive path including a connection land disposed on the relay portion; a temperature measurement element mounted on the mounting portion; a reinforcement member disposed along the mounting portion and the relay portion and fixed to the mounting portion; a conductive connection member connected to the electrode terminal; and a conductive relay member that electrically connects the connection land and the connection member to each other, in which the relay member includes a relay base portion connected to the connection member, and a plate spring portion that is continuous with the relay base portion, overlaps the relay portion and is electrically connected to the connection land, and biases the reinforcement member toward the temperature measurement surface.

Further, a power storage module disclosed in this specification includes: a power storage element provided with an electrode terminal and having a temperature measurement surface; and a wiring module attached to the power storage element, in which the wiring module includes a flexible substrate provided with a mounting portion, a relay portion that is continuous with the mounting portion, and a conductive path including a connection land disposed on the relay portion, a temperature measurement element mounted on the mounting portion, a reinforcement member disposed along the mounting portion and the relay portion and fixed to the mounting portion, a conductive connection member connected to the electrode terminal, and a conductive relay member that electrically connects the connection land and the connection member to each other, in which the relay member includes a relay base portion connected to the connection member, and a plate spring portion that is continuous with the relay base portion, overlaps the relay portion and is electrically connected to the connection land, and biases the reinforcement member toward the temperature measurement surface.

According to the above-described configuration, the reinforcement member is reliably kept in intimate contact with the temperature measurement surface, and heat generated by the power storage element is reliably transferred to the temperature measurement element via the reinforcement member and the mounting portion.

### Details of Embodiments

A specific example of a technique disclosed in this specification will be described below with reference to the following drawings. Note that the present invention is not limited to these examples, and is defined by the claims, and all changes that come within the meaning and range of equivalency of the claims are intended to be embraced therein.

### Embodiment

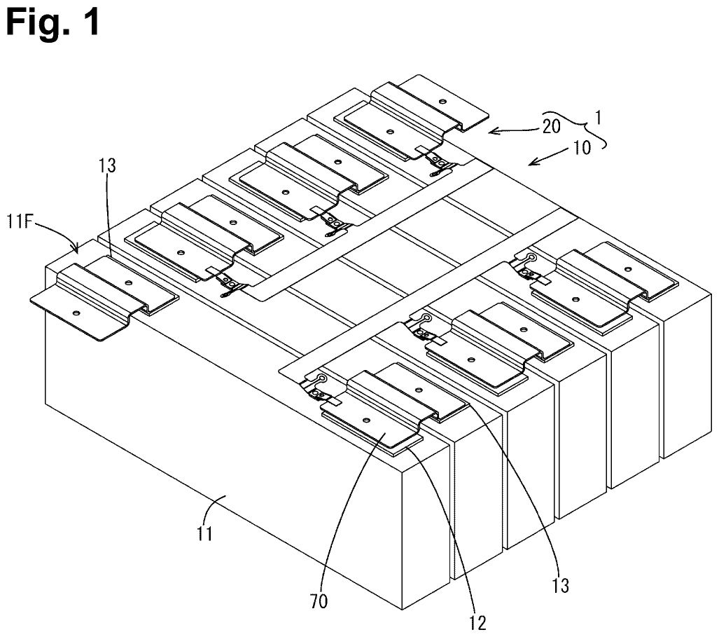

An embodiment will be described below with reference to FIGS. 1 to 6. A power storage module 1 according to this embodiment is a power supply device used as a drive source for electric automobiles or hybrid cars, and includes a plurality of power storage elements 10 and a wiring module 20 connected to the power storage elements 10, as shown in FIG. 1.

### Power Storage Element 10

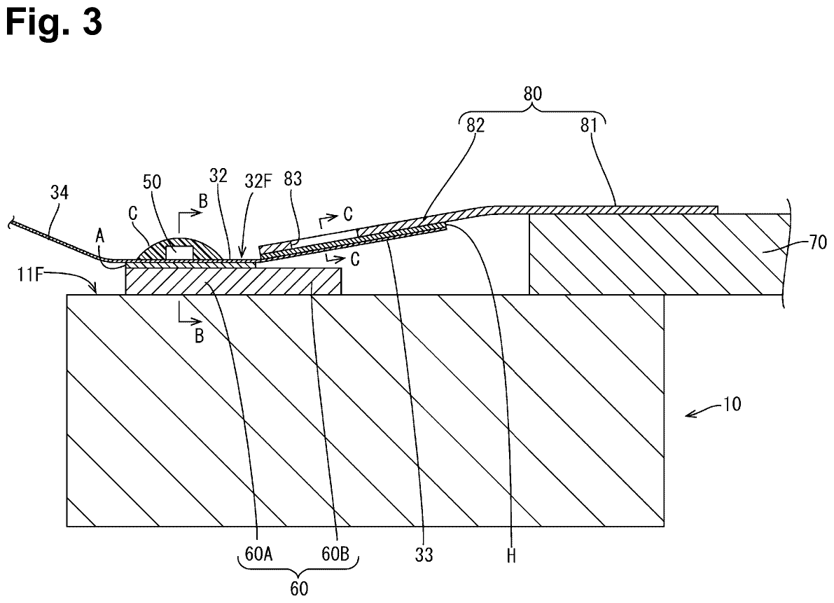

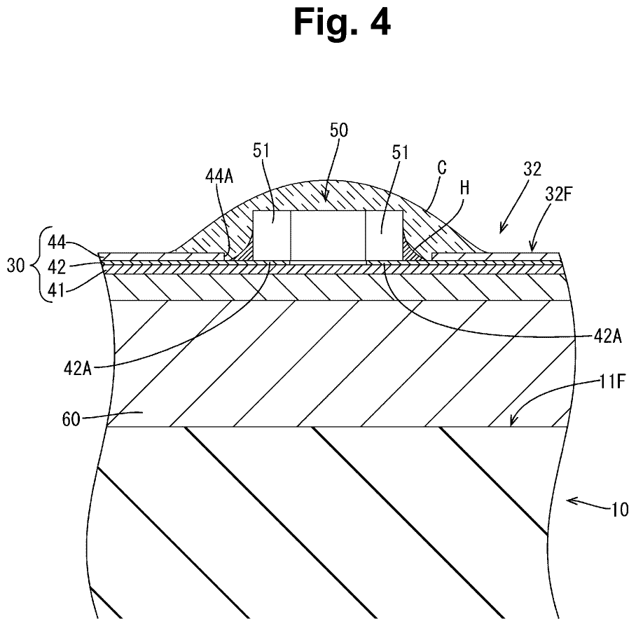

The power storage element 10 is a secondary battery, for example. Each power storage element 10 includes a metal case 11, and a power generating element is housed in the case 11. One of the outer surfaces of the case 11 (the upper surface in FIG. 1) is a temperature measurement surface 11F. Two electrode terminals 12 and 13 are disposed on the temperature measurement surface 11F. One of the two electrode terminals 12 and 13 is a positive terminal 12, and the other is a negative terminal 13. Note that FIGS. 3 and 4 do not show a detailed cross-section of the power storage element 10, but schematically show the entire power storage element 10.

The plurality of temperature measurement surfaces 11F of the plurality of power storage elements 10 are disposed flush with each other. Two adjacent power storage elements 10 are arranged such that electrode terminals 12 and 13 having different polarities are adjacent to each other, i.e., the positive terminal 12 of one power storage element 10 and the negative terminal 13 of another power storage element 10 that is adjacent to the power storage element 10 are arranged adjacent to each other.

### Wiring Module 20

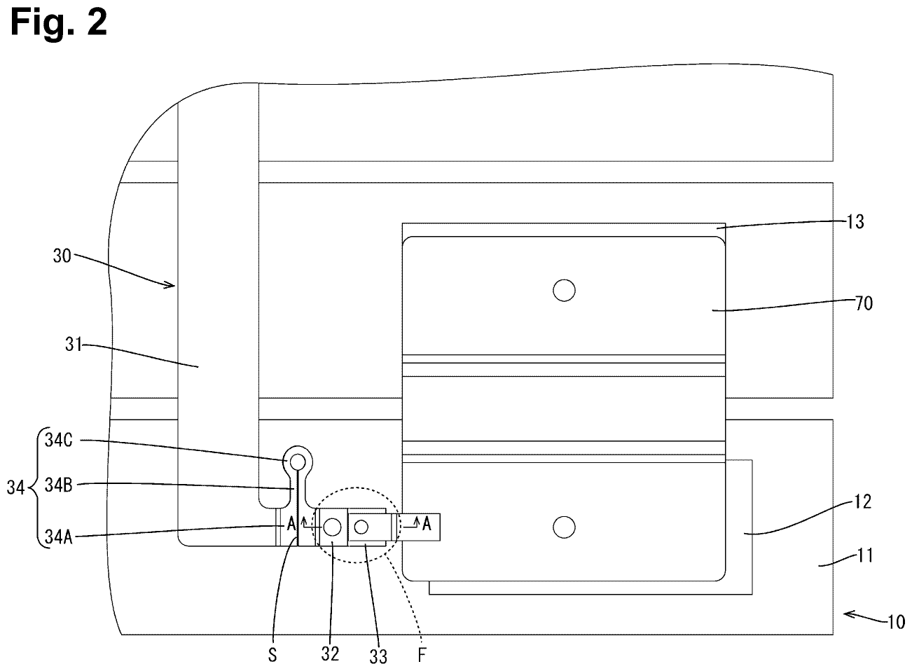

As shown in FIG. 2, the wiring module 20 is disposed along the temperature measurement surfaces 11F of the plurality of power storage elements 10. The wiring module 20 includes a flexible substrate 30, a plurality of temperature measurement elements 50 mounted on the flexible substrate 30, a reinforcement member 60 disposed overlapping the flexible substrate 30, a plurality of busbars 70 that connect adjacent electrode terminals 12 and 13 to each other, and relay members 80 that connect the flexible substrate 30 and the busbars 70.

### Temperature Measurement Element 50

The temperature measurement element 50 is a known thermistor element, for example. The temperature measurement element 50 includes two lead terminals 51.

### Flexible Substrate 30

The flexible substrate 30 is a flexible printed circuit board, and as shown in FIGS. 2 and 3, includes a strip-shaped substrate main body 31, a plurality of mounting portions 32 on which the temperature measurement elements 50 are mounted, a plurality of relay portions 33 that are respectively continuous with the plurality of mounting portions 32 and are connected to the corresponding relay members 80, and a plurality of movable portions 34 that connect the substrate main body 31 and the plurality of mounting portions 32 to each other.

As shown in FIG. 2, each movable portion 34 includes a movable portion main body 34A that connects the substrate main body 31 and the mounting portion 32 to each other, a protruding portion 34B that extends from the movable portion main body 34A, and a ring-shaped portion 34C connected to a leading end of the protruding portion 34B. The movable portion main body 34A and the protruding portion 34B have a slit S that extends from the ring-shaped portion 34C to a side edge of the movable portion main body 34A. Because the movable portion 34 has such a shape, the movable portion 34 is allowed to deform such that portions on two sides of the slit S separate from each other or deviate from the same plane. This allows free displacement of the mounting portion 32 and the relay portion 33 with respect to the substrate main body 31 to a certain extent.

As shown in FIGS. 4, 5, and 6, the flexible substrate 30 includes a base layer 41 constituted by an insulating film made of a synthetic resin, conductive paths 42 and 43 formed on one surface of the base layer 41 using printed wiring technology, and a cover lay 44 constituted by an insulating film made of a synthetic resin and covering the conductive paths 42 and 43. The conductive paths 42 and 43 are made of a metal such as copper or a copper alloy, and are conductive, for example. The conductive paths 42 and 43 respectively include a first conductive path 42 and a second conductive path 43. The flexible substrate 30 is disposed along a temperature measurement surface 11F with the surface on which the base layer 41 is disposed facing the temperature measurement surface 11F. The surface of the mounting portion 32 on which the cover lay 44 is disposed (the upper surface in FIG. 4) is a mounting surface 32F on which a temperature measurement element 50 is mounted.

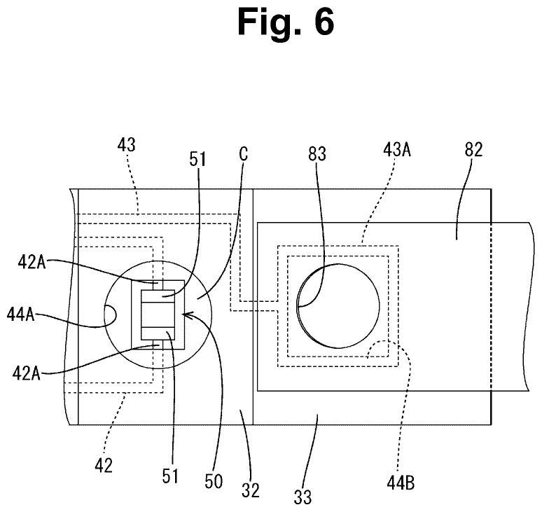

As shown in FIGS. 4 and 6, the temperature measurement element 50 is connected in series to the first conductive path 42. Portions of each first conductive path 42 disposed on each of a plurality of mounting portions 32 form two temperature measurement lands 42A. The cover lay 44 has a first opening portion 44A at a position where the temperature measurement element 50 is mounted, and the two temperature measurement lands 42A are exposed from the cover lay 44 inside the first opening portion 44A. The two lead terminals 51 of the temperature measurement element 50 are respectively connected to the two temperature measurement lands 42A. The lead terminal 51 and the temperature measurement land 42A are connected to each other with solder H, for example. The lead terminal 50 and the temperature measurement lands 42A are covered by an overcoat C made of a synthetic resin, for example.

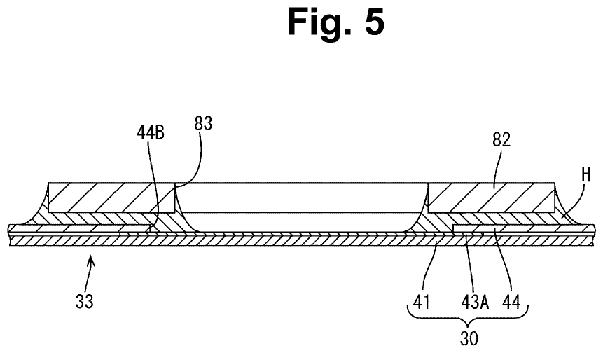

The second conductive path 43 is a voltage detection wire for detecting the voltage of the power storage element 10. As shown in FIGS. 5 and 6, the portion of the second conductive path 43 disposed on each of the plurality of relay portion 33 is a connection land 43A for connecting the relay member 80 to the flexible substrate 30. The cover lay 44 has a second opening portion 44B at a position where the connection land 43A is disposed, and a portion of the connection land 43A is exposed from the cover lay 44 inside the second opening portion 44B.

### Reinforcement Member 60

The reinforcement member 60 is a rigid plate-shaped member that does not have flexibility, and reinforces the mounting portion 32. As shown in FIG. 3, the reinforcement member 60 is disposed along the mounting portion 32 and the relay portion 33, and is fixed to a surface of the mounting portion 32 opposite to the mounting surface 32F (the surface on which the base layer 41 is disposed). A portion of the reinforcement member 60 is disposed along the mounting portion 32 and serves as a fixing portion 60A fixed to the mounting portion 32, and the remaining portion is disposed along the relay portion 33 and serves as an extending portion 60B that is not fixed to the relay portion 33. In this embodiment, the reinforcement member 60 is bonded to the mounting portion 32 using an adhesive A.

As shown in FIG. 3, the reinforcement member 60 is disposed in contact with the temperature measurement surface 11F. The reinforcement member 60 is preferably made of a metallic material having high thermal conductivity, and preferably made of aluminum or an aluminum alloy, for example. This is because the heat of the power storage element 10 is likely to be transferred to the temperature measurement element 50.

### Busbar 70

The busbar 70 is formed by a conductive metal plate member. Examples of a material of the busbar 70 include copper, a copper alloy, aluminum, an aluminum alloy, and stainless steel (SUS). In this embodiment, the busbar 70 is made of aluminum. As shown in FIGS. 1 and 2, the busbar 70 is placed on two adjacent electrode terminals 12 and 13, and is fixed to the electrode terminals 12 and 13 through laser welding, for example. As a result, the two adjacent electrode terminals 12 and 13 are electrically connected to each other.

### Relay Member 80

The relay member 80 is a conductive metal plate member, and electrically connects the second conductive path 43 and the busbar 70 to each other. The relay member 80 is preferably made of a metallic material that can be favorably joined to both the second conductive path 43 and the busbar 70. In this embodiment, the relay member 80 is made of nickel.

As shown in FIG. 3, the relay member 80 includes a plate-shaped relay base portion 81 connected to the busbar 70, and a plate-shaped plate spring portion 82 that extends obliquely from the relay base portion 81 and is connected to the relay portion 33, so as to have an overall plate shape that is bent to protrude to the opposite side to the temperature measurement surface 11F. The plate spring portion 82 has a through hole 83. As shown in FIG. 6, the through hole 83 is a hole whose hole edge shape smaller than the outer shape of the connection land 43A. The relay base portion 81 is placed on the busbar 70, and is electrically connected to the busbar 70 through laser welding, for example. As shown in FIG. 5, the plate spring portion 82 overlaps the surface of the relay portion 33 on which the cover lay 44 is disposed, and is electrically connected to the connection land 43A exposed from the cover lay 44. In this embodiment, the plate spring portion 82 is connected to the connection land 43A using solder H.

### Attachment of Wiring Module 20 to Power Storage Element 10

As shown in FIGS. 1 and 2, when a wiring module 20 is attached to a power storage element 10, the wiring module 20 is disposed along the temperature measurement surfaces 11F of the plurality of power storage elements 10 that are arranged in parallel, and each busbar 70 is fixed to the electrode terminals 12 and 13 through laser welding. As described above, the movable portion 34 is allowed to deform to a certain extent. Therefore, the mounting portion 32, the relay portion 33, the relay member 80, and the busbar 70 are allowed to be freely displaced with respect to the substrate main body 31 to a certain extent. This makes it possible to easily attach the wiring module 20 to the power storage element 10.

As shown in FIG. 3, the reinforcement member 60 is in contact with the temperature measurement surface 11F in a state in which the wiring module 20 is attached to the power storage element 10. The plate spring portion 82 and the relay portion 33 are inclined in a direction away from the reinforcement member 60 toward the relay base portion 81. When the reinforcement member 60 attempts to be displaced in a direction in which the reinforcement member 60 moves upward from the temperature measurement surface 11F, the plate spring portion 82 attempts to deform in a direction in which the angle of the plate spring portion 82 relative to the relay base portion 81 increases, and thus the resulting elastic restoring force biases the reinforcement member 60 toward the temperature measurement surface 11F. As a result, the reinforcement member 60 is reliably kept in intimate contact with the temperature measurement surface 11F, and heat generated by the power storage element 10 is reliably transferred to the temperature measurement element 50 via the reinforcement member 60 and the mounting portion 32.

### Effects

As described above, according to this embodiment, the power storage module 1 includes: the power storage elements 10 provided with the electrode terminals 12 and 13 and having the temperature measurement surfaces 11F; and the wiring module 20 attached to the power storage elements 10, in which the wiring module 20 includes the mounting portion 32 and the relay portion 33 that is continuous with the mounting portion 32, the flexible substrate 30 provided with the conductive paths 42 and 43 including the connection land 43A disposed on the relay portion 33, the temperature measurement element 50 mounted on the mounting portion 32, the reinforcement member 60 that is disposed along the mounting portion 32 and the relay portion 33 and is fixed to the mounting portion 32, the conductive busbar 70 connected to the electrode terminals 12 and 13, and the conductive relay member 80 that electrically connects the connection land 43A and the busbar 70 to each other, in which the relay member 80 includes the relay base portion 81 connected to the busbar 70, and the plate spring portion 82 that is continuous with the relay base portion 81, overlaps the relay portion 33 and is electrically connected to the connection land 43A, and biases the reinforcement member 60 toward the temperature measurement surface 11F.

According to the above-described configuration, the reinforcement member 60 is reliably kept in intimate contact with the temperature measurement surface 11F, and heat generated by the power storage element 10 is reliably transferred to the temperature measurement element 50 via the reinforcement member 60 and the mounting portion 32.

### Other Embodiments

(1) Although an example in which the relay member 80 is fixed to the busbar 70 through laser welding has been described in the above embodiment, a method for connecting the relay member and the busbar to each other is not limited to the above embodiment, and the relay member and the busbar may be connected using ultrasonic welding, soldering, or crimping, for example.

(2) Although an example in which the reinforcement member 60 is made of a metallic material has been described in the above embodiment, the reinforcement member may be made of a material other than a metal, and may be made of resin, for example.

### LIST OF REFERENCE NUMERALS

1 Power storage module
10 Power storage element
11 Case
11F Temperature measurement surface
12 Positive terminal (electrode terminal)
13 Negative terminal (electrode terminal)
20 Wiring module
30 Flexible substrate
31 Substrate main body
32 Mounting portion
32F Mounting surface
33 Relay portion
34 Movable portion
34A Movable portion main body
34B Protruding portion
34C Ring-shaped portion
41 Base layer
42 First conductive path (conductive path)
42A Temperature measurement land
43 Second conductive path (conductive path)
43A Connection land
44 Cover lay
44A First opening portion
44B Second opening portion
50 Temperature measurement element
51 Lead terminal
60 Reinforcement member
60A Fixing portion
60B Extending portion
70 Busbar
80 Relay member
81 Relay base portion
82 Plate spring portion
83 Through hole
A Adhesive
C Overcoat
H Solder

S Slit

1. A wiring module to be attached to a power storage element provided with an electrode terminal and having a temperature measurement surface, the wiring module comprising:
a flexible substrate provided with a mounting portion, a relay portion that is continuous with the mounting portion, and a conductive path including a connection land disposed on the relay portion;
a temperature measurement element mounted on the mounting portion;
a reinforcement member disposed along the mounting portion and the relay portion and fixed to the mounting portion;
a conductive connection member connected to the electrode terminal; and
a conductive relay member that electrically connects the connection land and the connection member to each other,
wherein the relay member includes
a relay base portion connected to the connection member, and
a plate spring portion that is continuous with the relay base portion, overlaps the relay portion and is electrically connected to the connection land, and biases the reinforcement member toward the temperature measurement surface.

2. A power storage module comprising:
a power storage element provided with an electrode terminal and having a temperature measurement surface; and
a wiring module attached to the power storage element,
wherein the wiring module includes
a flexible substrate provided with a mounting portion, a relay portion that is continuous with the mounting portion, and a conductive path including a connection land disposed on the relay portion,
a temperature measurement element mounted on the mounting portion,
a reinforcement member disposed along the mounting portion and the relay portion and fixed to the mounting portion,
a conductive connection member connected to the electrode terminal, and
a conductive relay member that electrically connects the connection land and the connection member to each other,
wherein the relay member includes
a relay base portion connected to the connection member, and
a plate spring portion that is continuous with the relay base portion, overlaps the relay portion and is electrically connected to the connection land, and biases the reinforcement member toward the temperature measurement surface.
